(19) United States
(12) Patent Application Publication
(10) Pub. No.: US 2002/0167072 A1
(43) Pub. Date: Nov. 14, 2002

(54) Electrostatically actuated micro-electro-mechanical devices and method of manufacture

(76) Inventor: Robert George Andosca, Nashua, NH (US)

Correspondence Address: HALE AND DORR, LLP, 60 STATE STREET, BOSTON, MA, 02109

(21) Appl. No.: 10/099,153

(22) Filed: Mar. 15, 2002

Related U.S. Application Data
(60) Provisional application No. 60/276,319, filed on Mar. 16, 2001.

(51) Int. Cl. H01L 23/544

(52) U.S. Cl. 257/620

(57) ABSTRACT

In accordance with one embodiment, a method is provided for fabricating electrodes for an electrostatically actuated MEMS device. The method includes patterning a surface of a wafer to define trenches to be etched, with each trench having an area selected in accordance with a desired depth; etching the surface of the wafer to form the trenches with the etch rate being varied in accordance with the trench area such that the trenches have depths determined by their respective areas; depositing an electrically conductive material in the trenches to form the electrodes; and removing portions of the wafer surrounding the electrodes. In accordance with another embodiment, a method of fabricating an electrostatically actuated MEMS mirror device is provided. The method includes providing a structure having a wafer including a trenches filled with material forming electrodes, and a mirror structure supported on the wafer above the trenches, the mirror structure including a mirror and a suspension mechanism for supporting the mirror with respect to the wafer, the mirror structure being covered by a protective layer; selectively etching the structure to expose the electrodes and to release the mirror structure such that the mirror is suspended by the suspension mechanism above the electrodes; and removing the protective layer from the mirror structure. In accordance with another embodiment, an electrostatically actuated MEMS mirror device formed from a double-bonded wafer stack is provided. The device includes a middle wafer having raised and inclined steering electrodes; a top wafer including a mirror structure having a mirror and a suspension mechanism for rotatably supporting the mirror above and with respect to the steering electrodes; and a handle wafer positioned below the middle wafer for providing front-side or back-side contacts for the electrodes.

### RELATED APPLICATION

The present application is based on and claims priority from U.S. Provisional Patent Application Serial No. 60/276, 319 filed on Mar. 16, 2001 and entitled Method for Fabricating an Electrostatically Actuated Silicon Mirror.

### BACKGROUND OF THE INVENTION

1. Field of the Invention

The present invention relates generally to micro-electro-mechanical system (MEMS) devices and, in particular, to arrayed electrostatically actuated MEMS devices such as, e.g., arrayed micro-mirrors used in optical switches.

2. Description of Related Art

One example of the use of an electrostatically actuated MEMS device is in an optical switch. FIG. 1 schematically illustrates an example of an optical cross-connect 12 of an optical switch. The cross-connect 12 includes an array of collimators or other beam-forming devices (represented by grid 14), which forms incoming optical communications signals into beams that impinge on an array of moveable reflectors or mirrors represented by grid 16. Each beam from grid 14 has its own corresponding moveable mirror on grid 16.

The moveable mirrors of grid 16 are controllably positioned so as to individually direct the respective beams from grid 14 to respective moveable mirrors of a second array of moveable mirrors represented by grid 18. The moveable mirrors of grid 18 are positioned so as to individually direct the beams received from grid 16 to respective beam receivers of an array of beam receivers represented by grid 20. The beam receivers can take various forms such as transducers or optical elements for coupling the respective beams into respective waveguides, or the like. As with grids 14 and 16, each moveable mirror of grid 18 is associated with a particular beam receiver of grid 20, so that each receiver receives beams on a single axis. The arrow 22 shows a representative signal path from grid 14 to grid 20.

The movable mirrors can be steered or controllably tilted about one or more axes. Mirror movement can be actuated in a variety of ways including through electromagnetic actuation, electrostatic actuation, piezoelectric actuation, stepper motors, thermal bimorph actuation and comb-drive actuation.

In electrostatically actuated mirror arrays, each mirror in the array is rotatably mounted on a base structure having a set of steering electrodes. The steering electrodes can be selectively actuated to generate electrostatic forces to tilt the mirror to a desired position.

Attempts have been made previously to fabricate arrays of movable mirrors using MEMS technology, in which silicon processing and related techniques common to the semiconductor industry are used to form micro-electro-mechanical devices.

### BRIEF SUMMARY OF EMBODIMENTS OF THE INVENTION

The present invention is directed to improved electrostatically actuated MEMS devices and methods of manufacturing such devices.

In accordance with one embodiment of the invention, a method is provided for fabricating electrodes for an electrostatically actuated MEMS device. The method includes patterning a surface of a wafer to define trenches to be etched, with each trench having an area selected in accordance with a desired depth; etching the surface of the wafer to form the trenches with the etch rate being varied in accordance with the trench area such that the trenches have depths determined by their respective areas; depositing an electrically conductive material in the trenches to form the electrodes; and removing portions of the wafer surrounding the electrodes.

In accordance with another embodiment, a method of fabricating an electrostatically actuated MEMS mirror device is provided. The method includes providing a structure having a wafer including a trenches filled with material forming electrodes, and a mirror structure supported on the wafer above the trenches, the mirror structure including a mirror and a suspension mechanism for supporting the mirror with respect to the wafer, the mirror structure being covered by a protective layer; selectively etching the structure to expose the electrodes and to release the mirror structure such that the mirror is suspended by the suspension mechanism above the electrodes; and removing the protective layer from the mirror structure.

In accordance with another embodiment, an electrostatically actuated MEMS mirror device formed from a double-bonded wafer stack is provided. The device includes a middle wafer having raised and inclined steering electrodes; a top wafer including a mirror structure having a mirror and a suspension mechanism for rotatably supporting the mirror above and with respect to the steering electrodes; and a handle wafer positioned below the middle wafer for providing front-side or back-side contacts for the electrodes.

These and other features of the present invention will become readily apparent from the following detailed description wherein embodiments of the invention are shown and described by way of illustration of the best mode of the invention. As will be realized, the invention is capable of other and different embodiments and its several details may be capable of modifications in various respects, all without departing from the invention. Accordingly, the drawings and description are to be regarded as illustrative in nature and not in a restrictive or limiting sense with the scope of the application being indicated in the claims.

### BRIEF DESCRIPTION OF THE DRAWINGS

For a fuller understanding of the nature and objects of the present invention, reference should be made to the following detailed description taken in connection with the accompanying drawings wherein:

FIG. 1 is a schematic illustration of an example of an optical cross-connect;

FIG. 2A is a schematic cross-sectional view of a mirror pixel device in accordance with one embodiment of the invention;

FIG. 2B is a schematic cross-sectional view of a mirror pixel device in accordance with another embodiment of the invention;

FIG. 2C is a schematic cross-sectional view of a mirror pixel device in accordance with another embodiment of the invention;

FIGS. 3A-3F are schematic cross-sectional views illustrating the fabrication of the handle layer of the mirror pixel device shown in FIG. 2A;

FIGS. 4A-4D are schematic cross-sectional views illustrating the fabrication of the handle layer of the mirror pixel device shown in FIG. 2B;

FIGS. 5A-5C are schematic cross-sectional views illustrating the fabrication of the handle layer of the mirror pixel device shown in FIG. 2C;

FIGS. 6A-6F are schematic cross-sectional views illustrating the fabrication of a middle wafer layer having steering electrodes of the mirror pixel device shown in FIGS. 2A-2C;

FIGS. 7A-7J are schematic cross-sectional views illustrating the fabrication of the of the mirror pixel device shown in FIG. 2A using the middle wafer layer fabricated as shown in FIGS. 6A-6F and the handle layer fabricated as shown in FIGS. 3A-3F; and

FIGS. 8A-8F are schematic cross-sectional views illustrating the fabrication of the of the mirror pixel device shown in FIG. 2B using the middle wafer layer fabricated as shown in FIGS. 6A-6F and the handle layer fabricated as shown in FIGS. 4A-4D.

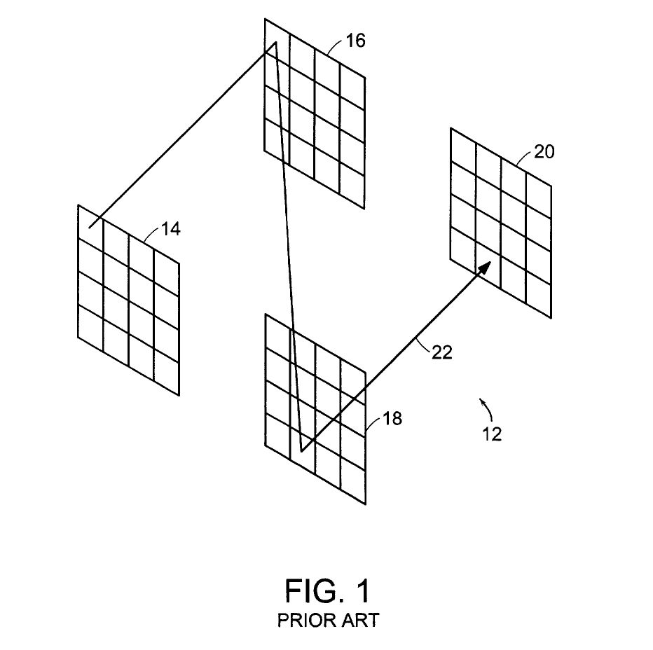

### DETAILED DESCRIPTION OF THE PREFERRED EMBODIMENT

The present invention is generally directed to improved electrostatically actuated MEMS mirror devices and methods of manufacturing such devices.

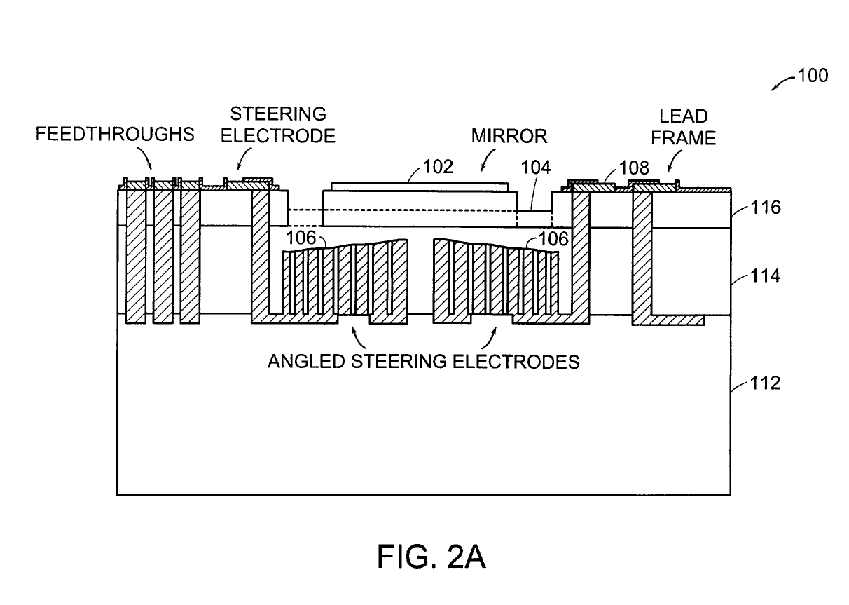

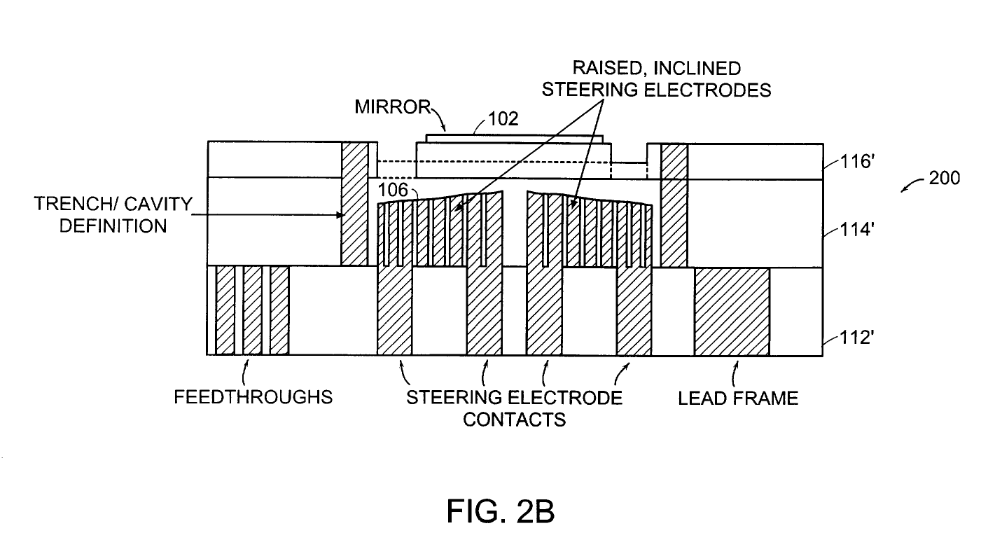

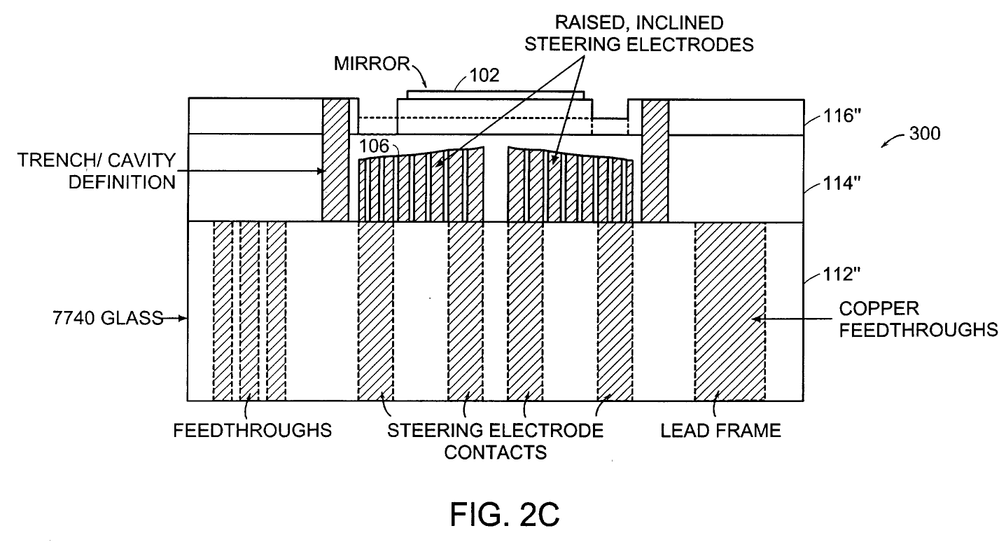

FIG. 2A illustrates a single electrostatically actuated mirror device or pixel 100 in accordance with one embodiment of the invention. The pixel can be part of a mirror array comprising a plurality of such pixels used, e.g., in an optical cross-connect of an optical switch. The mirror device 100 includes a mirror structure 102 having an exposed reflective surface. The mirror structure 102 is movably supported on the pixel using, e.g., a suspension spring mechanism 104, such that the mirror 102 can be tilted about generally any axis in the plane of the device. The suspension spring mechanism 104 can comprise, e.g., a gimbal mechanism.

The mirror device 100 also includes a set of steering electrodes 106 beneath the mirror, which can be selectively actuated to generate electrostatic forces to tilt the mirror in a desired direction. The electrodes 106 are shaped (rather than planar) in cross-section, and are preferably sloped or inclined as shown, e.g., in FIG. 2A. The electrodes 106 can be highest near the center of the mirror structure 102, and gradually decrease in height to a minimum near the outer edges of the mirror structure 102.

The raised electrode configuration increases the electrostatic forces applied to the mirror structure 102 (compared to planar electrodes) and thereby lowers the needed voltage for a given angular displacement. The shaped electrodes 106 are thereby able to provide high angular deflection using lower actuation voltages.

Electrical connections can be provided to the steering electrodes by electrode contacts 108, which can be, e.g., front side contacts as shown in FIG. 2A. Alternatively, backside flip-chip contacts can be provided as shown, e.g., in the mirror devices 200, 300 of FIGS. 2B and 2C.

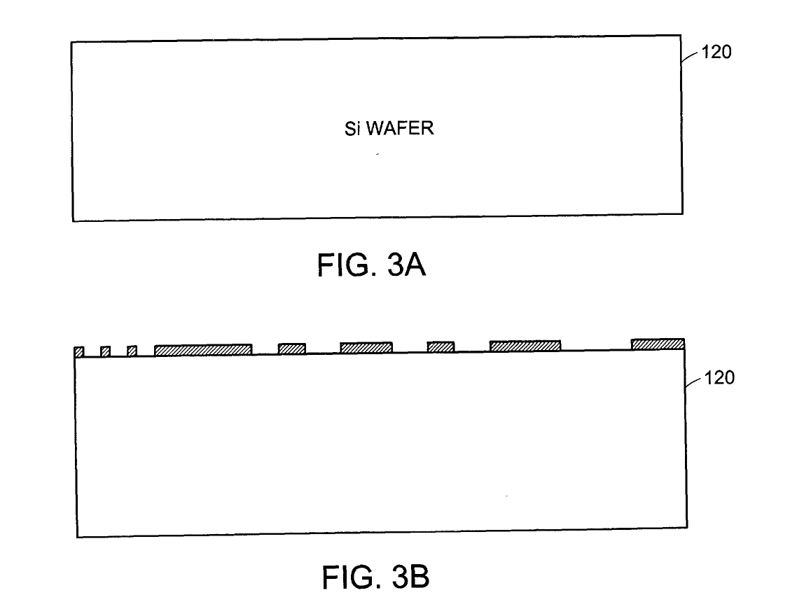

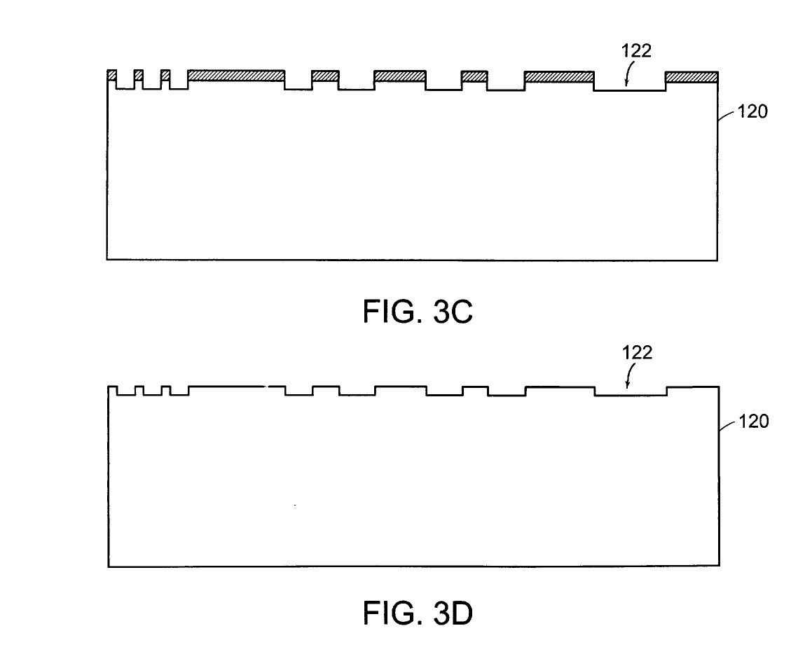

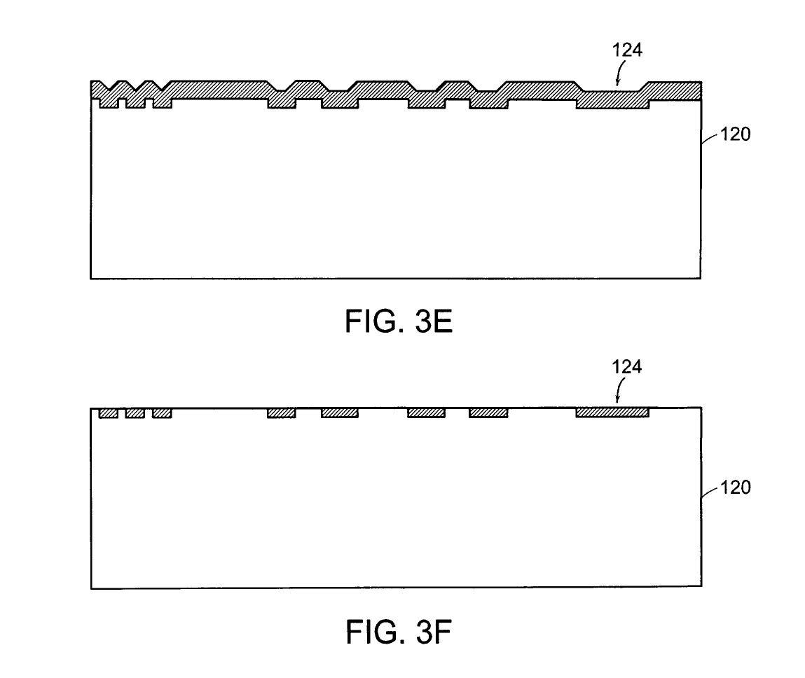

FIGS. 3-8 schematically illustrate exemplary methods of fabricating electrostatically actuated silicon mirror devices such as the FIGS. 2A-2C devices. The devices can be fabricated as double bonded three wafer stacks with interconnects, preferably trench and polysilicon filled interconnects. Each wafer stack can comprise a handle wafer 112, a middle wafer 114, and a top wafer 116.

The handle wafer 112, 112′, 112″ includes electrode interconnects for either front-side bonding as shown in FIG. 2A or for backside (flipchip) bonding as shown in FIGS. 2B and 2C. The middle silicon wafer 114, 114′, 114″ includes the raised, inclined steering electrodes, which can be polysilicon electrodes. The top silicon wafer 116, 116′, 116″ includes the movable mirror structure. The devices can be fabricated using wafer bonding techniques that are used, e.g., in producing silicon on insulator wafers.

FIGS. 3A-3F schematically illustrate an exemplary method of fabricating the handle wafer 112 of the FIG. 2A device 200, which has frontside electrode contacts. A starting silicon wafer substrate 120 (shown in FIG. 3A) is patterned and etched to form trenches for the interconnect, actuator, and lead transfer electrodes. The trenches 122 can be patterned as shown, e.g., in FIG. 3B, and etched by, e.g., a Si RIE (reactive ion etch) etch as shown in FIG. 3C. A photo strip process is then performed as shown in FIG. 3D, followed by oxidation of the surfaces of the trenches, leaving a layer of dielectric SiO2 lining the trenches. As shown in FIG. 3E, the etched, SiO2 lined trenches can then be filled with polysilicon 124. The polysilicon layer can then be polished to flatness as shown in FIG. 3F using, e.g., standard CMP (chemical/mechanical polishing) techniques. The polysilicon can then be doped with phosphorus, and the wafer subjected to a phosphorus glass dip.

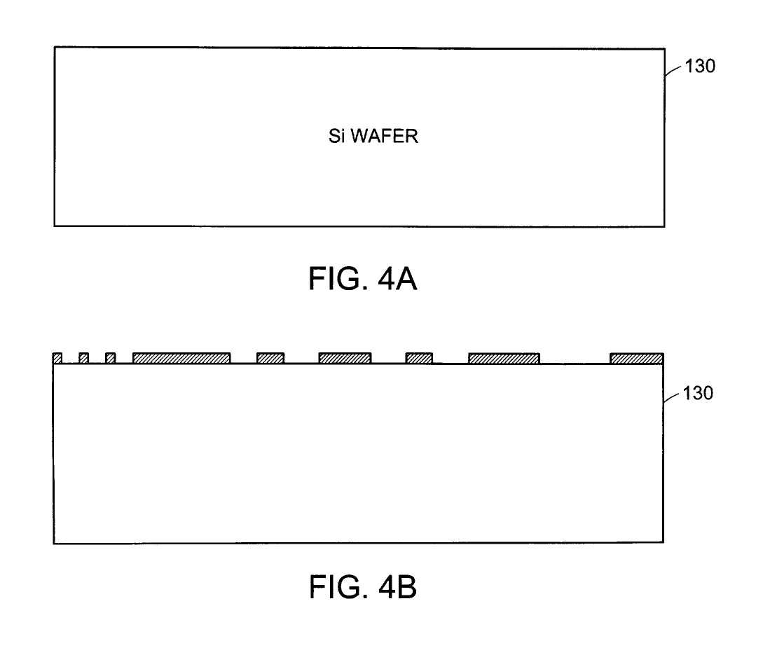

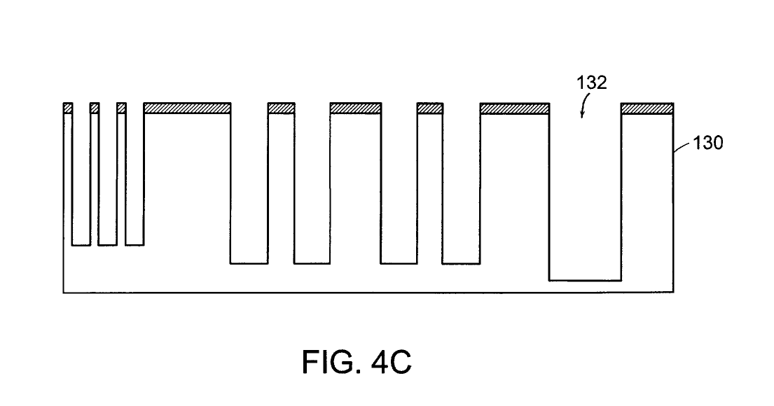

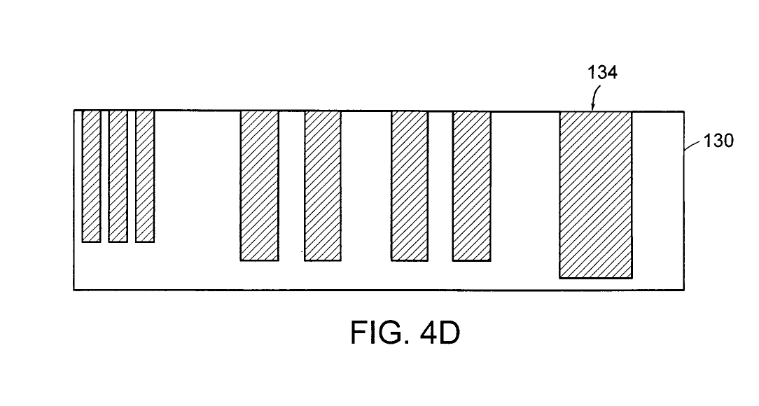

FIGS. 4A-4D schematically illustrate an exemplary method of fabricating the handle wafer 112′ of the FIG. 2B device 300, which has back side electrode contacts. A starting silicon wafer substrate 130 (shown in FIG. 4A) is patterned (as shown in FIG. 4B) to form trenches 132 for interconnect, actuator, and lead transfer electrodes. Etching, preferably deep RIE, is performed to form the trenches 132 shown in FIG. 4C. As shown in FIG. 4D, a photo strip process is then performed, followed by a lining of the stripped trenches with tetraethylorthosilicate-derived SiO2. The lined electrodes are filled with polysilicon 134, and the electrode surface is polished by CMP to flatness. The electrodes can be doped with phosphorus.

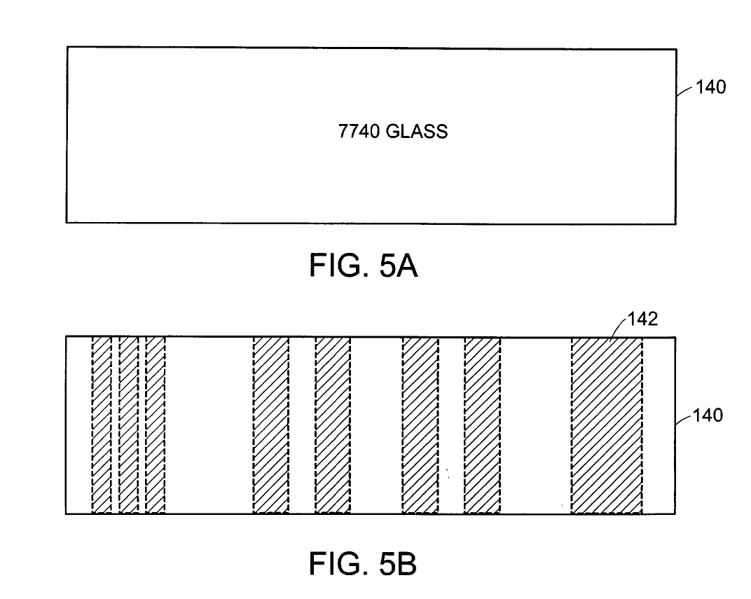

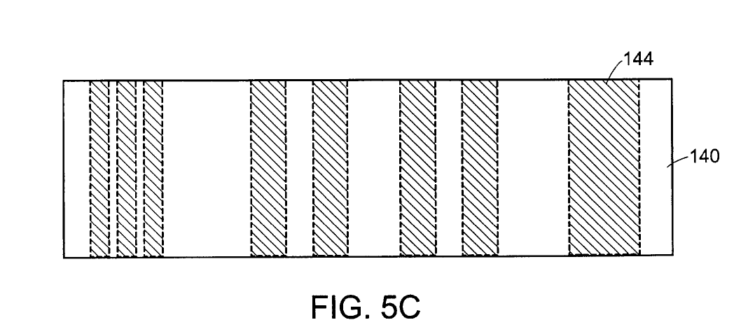

FIGS. 5A-5C schematically illustrate an exemplary method of fabricating the handle wafer of the FIG. 2C device, which also has back side electrode contacts. In a glass substrate 140 (shown in FIG. 5A) such as, e.g., Corning 7740 glass, holes 142 are patterned and etched therethrough as shown in FIG. 5B. The holes are filled by copper electroplating 144, and the surfaces are polished by standard CMP techniques as shown in FIG. 5C.

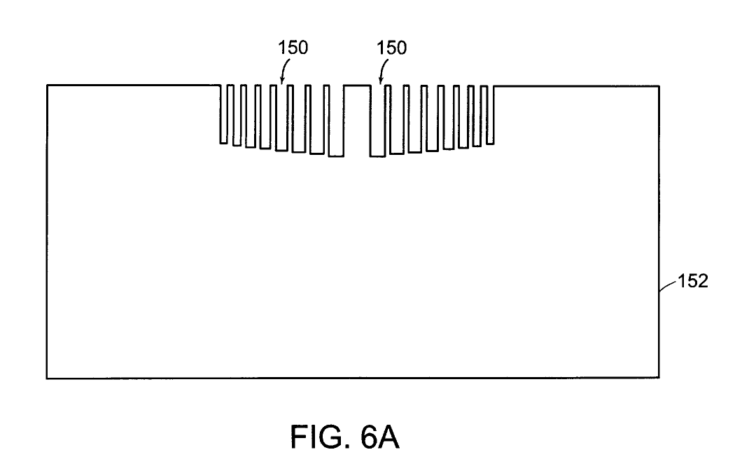

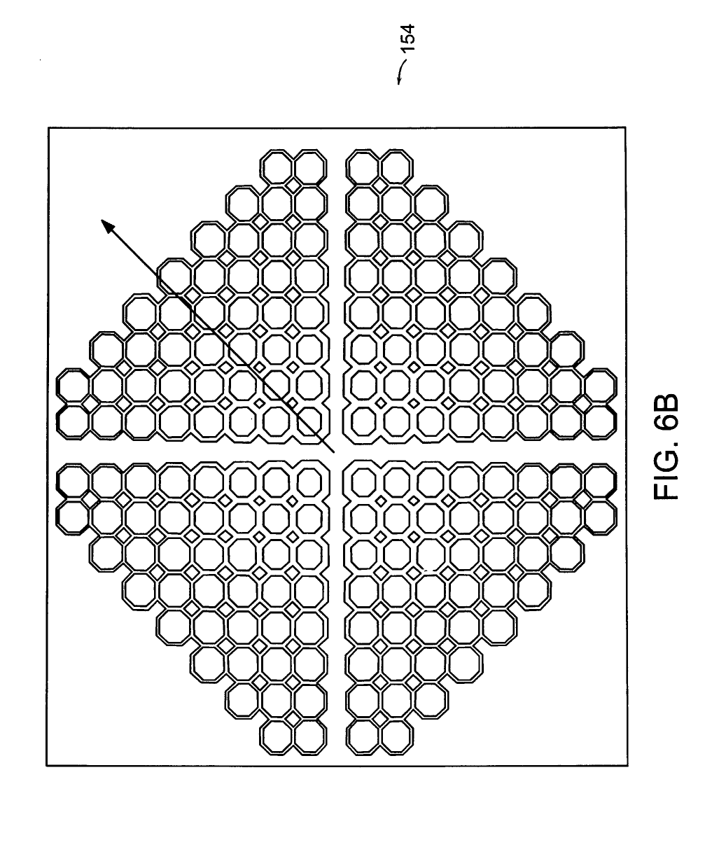

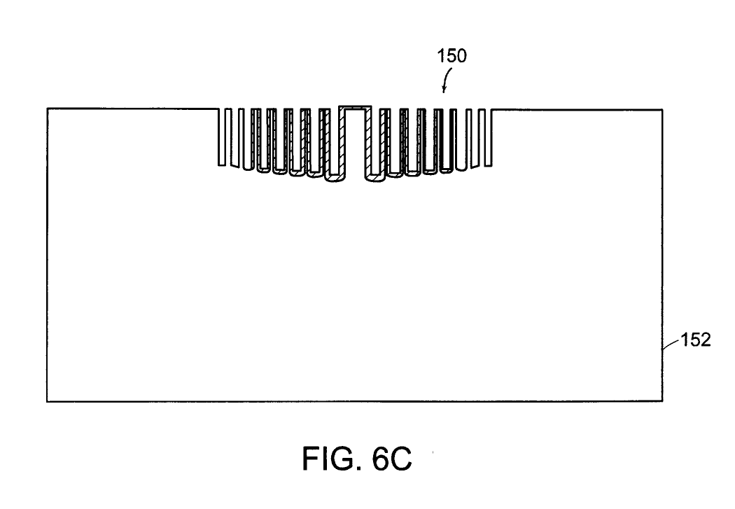

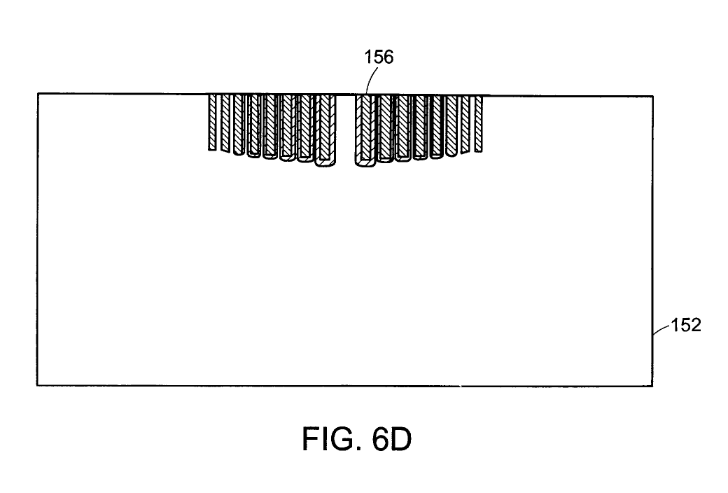

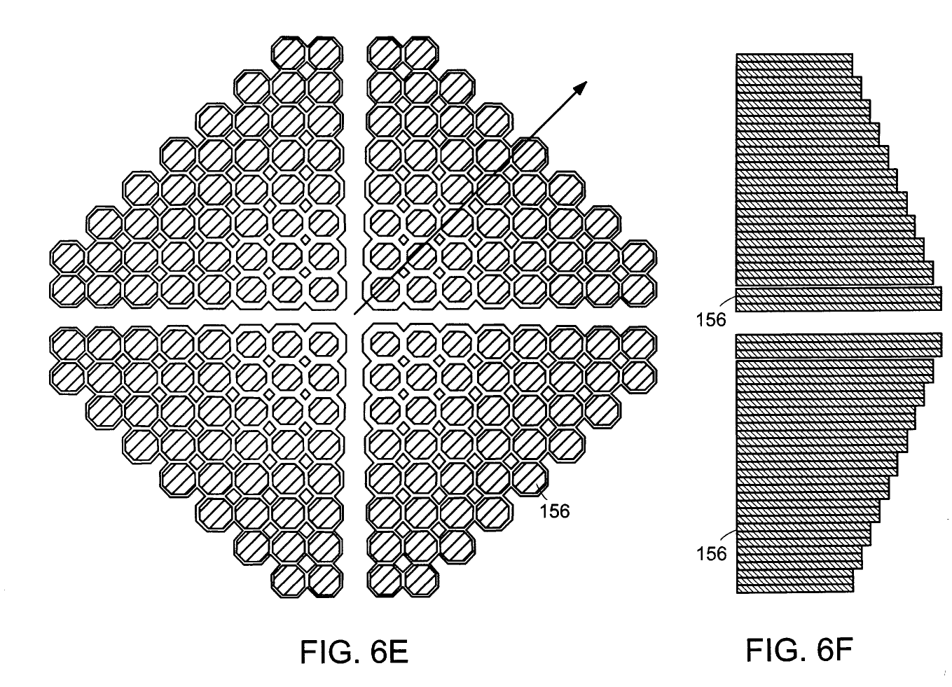

FIGS. 6A-6F schematically illustrate an exemplary method of fabricating the middle wafer 114 containing the shaped steering electrodes. FIG. 6A shows the patterning and etching of the trenches (i.e., holes or etched areas) 150 that are later filled to form the raised, inclined steering electrodes. The surface of a silicon wafer 152 is patterned with a photolithography mask having a structure in which the trench widths or areas decrease radially. One example of such a photolithography mask 154 is shown in FIG. 6B, which is a plan view of the mask. In this example, the mask has a honeycomb-like structure. A highly directional silicon etch process (such as, e.g., the Bosch™ etch process) is used with the mask. The “micro-loading” effect of highly directional silicon etch processes causes the etch rate of the silicon to decrease with decreasing trench widths or areas. Since in this example, the trench widths or areas decrease radially, the depth of the trenches likewise decreases radially, as shown in FIG. 6A.

As shown in FIG. 6C, the surfaces of the trenches 150 are oxidized to provide a layer of dielectric SiO2. The trenches are then filled with polysilicon as shown in FIG. 6D to form electrodes 156. This may be performed by, e.g., filling with in situ doped polysilicon. Alternatively, the trenches can be partially filled with polysilicon, doped with phosphorus, completely filled with polysilicon, again doped with phosphorus, and finally annealed. The top surface of the polysilicon-filled trenches is polished to flatness by a standard CMP technique. FIGS. 6E and 6F show top and side views, respectively, of the polysilicon electrodes, which are embedded in the silicon wafer, as shown in FIG. 6D.

Using the anisotropy or micro-loading effects of a highly directional silicon etch process (e.g., the Bosch™ etch process) to define the different heights of the raised, inclined steering electrodes provides several advantages over other methods that could be used to define such a structure. Forming the electrodes using traditional methods would require one masking and etching cycle for each desired electrode height. In this process, however, the electrodes are patterned by a single masking and etching step, with the height of the electrode determined by the width or area of the corresponding trench. This process allows for a greatly simplified fabrication of raised, inclined structures.

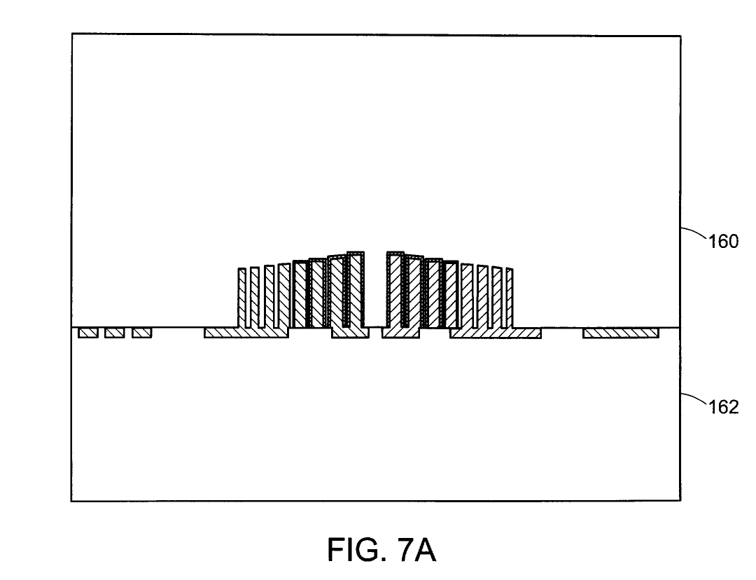

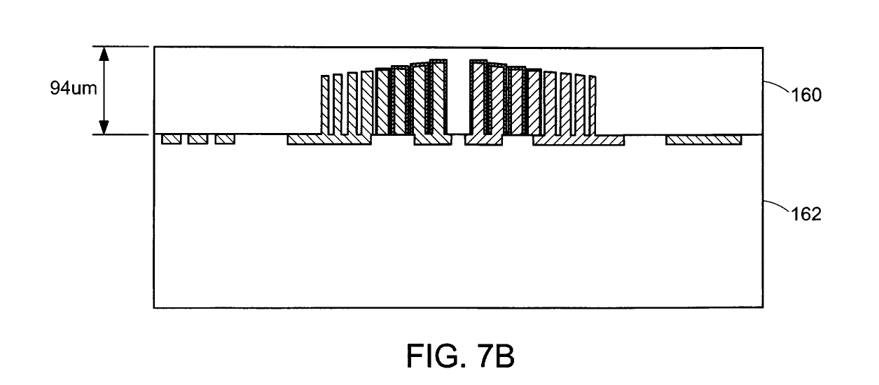

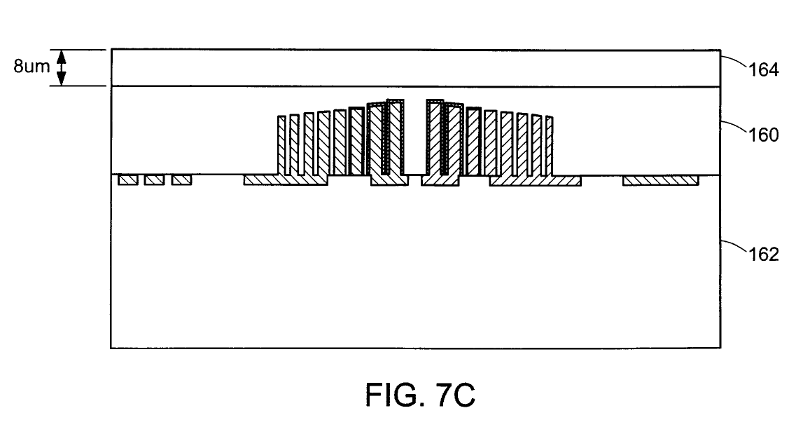

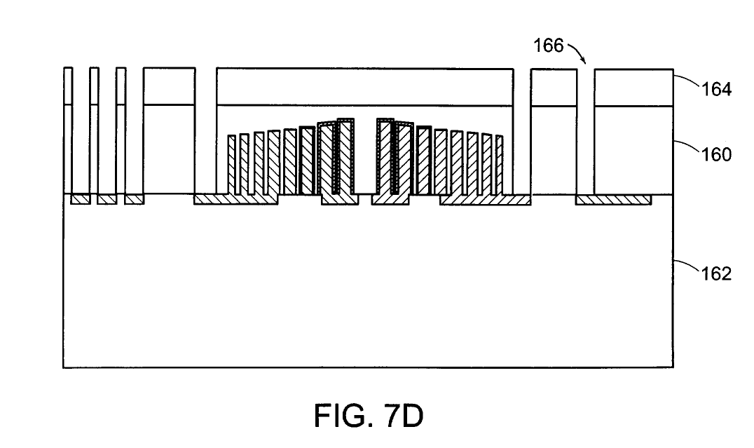

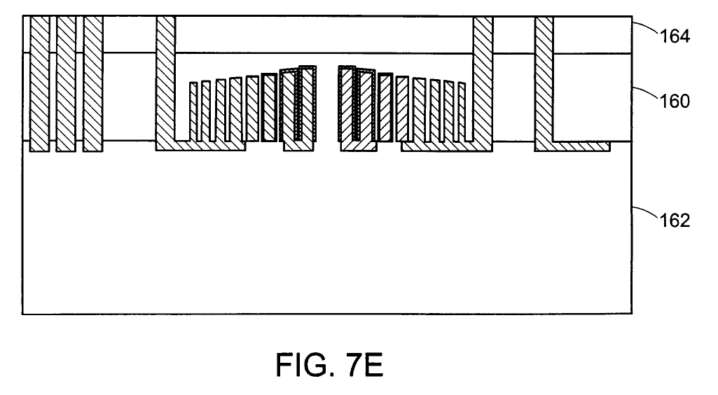

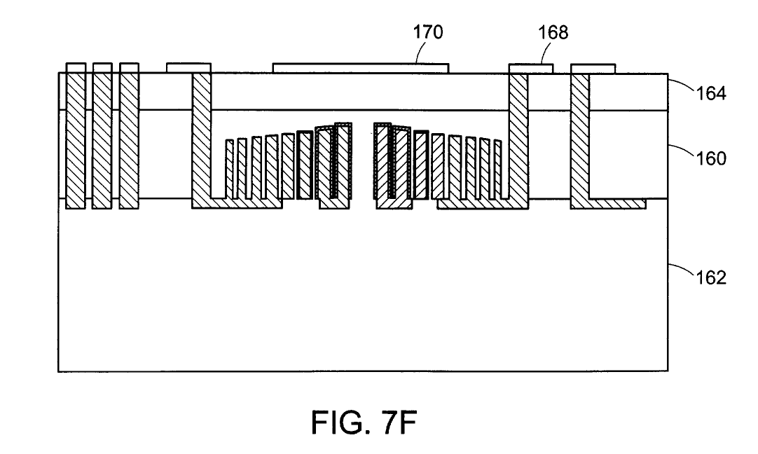

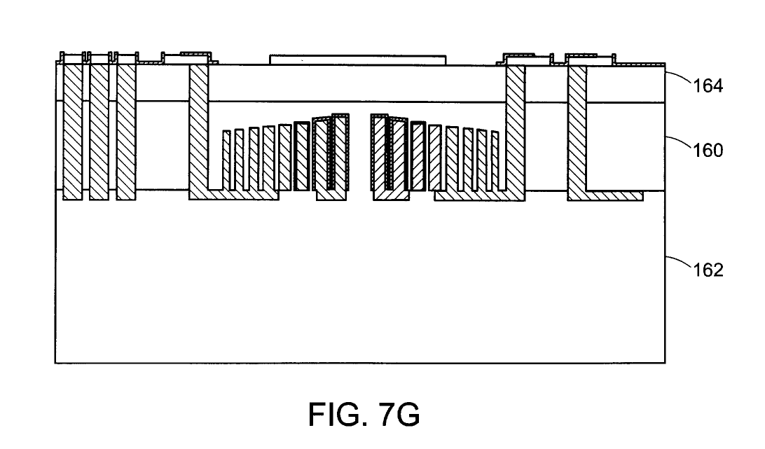

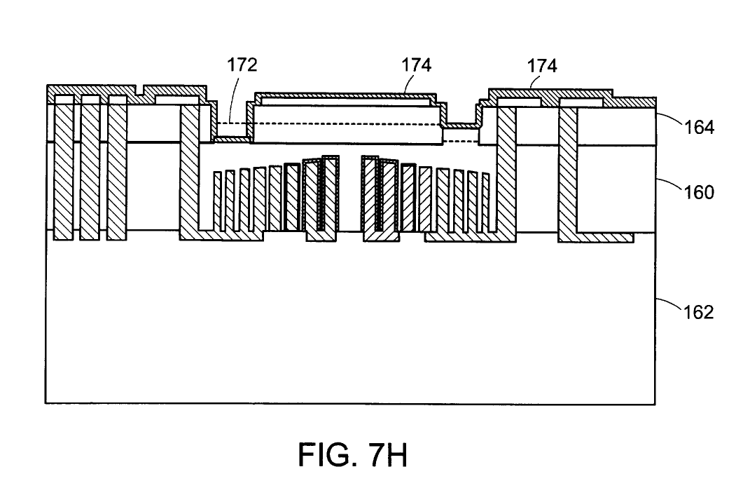

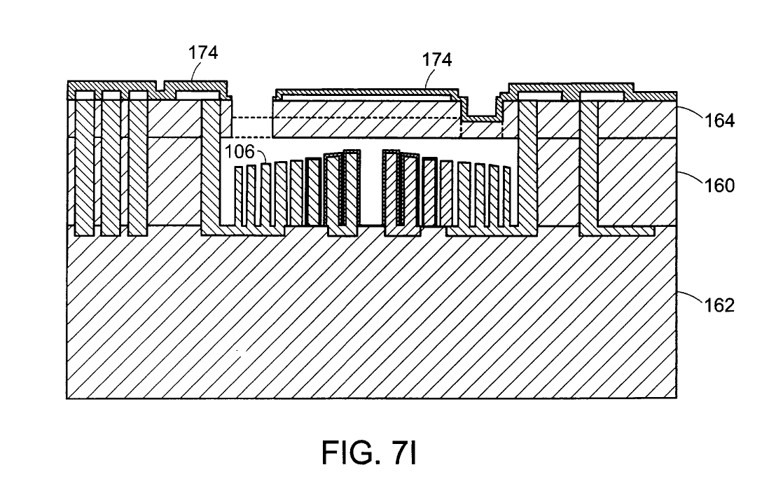

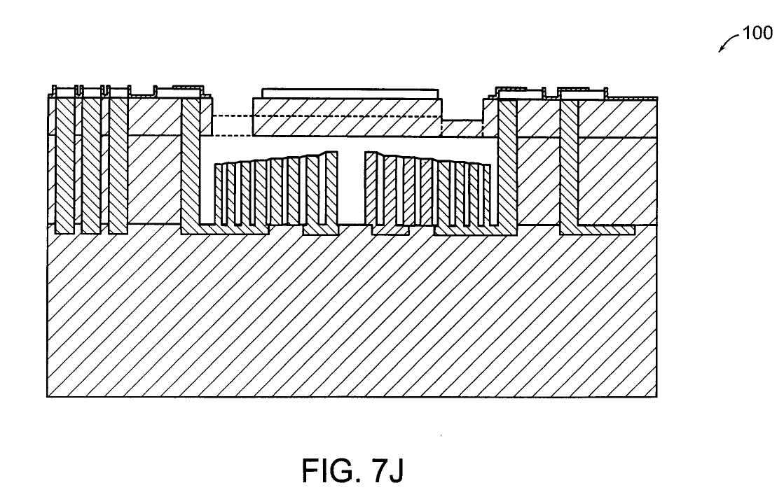

FIGS. 7A-7J schematically illustrate an exemplary method for assembling the mirror device 100 with front-side contacts shown in FIG. 2A. As shown in FIG. 7A, the middle wafer 160 (formed, e.g., as described above with respect to FIGS. 6A-6F) is inverted and aligned to the handle wafer 162 (formed, e.g., as described above with respect to FIGS. 3A-3F). The wafers are then bonded and annealed (e.g., at 1200 degrees C. for two hours in steam). As shown in FIG. 7B, the top surface of the two-wafer stack (which was previously the bottom surface of the middle wafer) is ground and polished so that the thickness of the middle wafer is reduced to about 94 microns. As shown in FIG. 7C, a wafer 164 from which the mirror will be formed is bound to the polished top surface of the two-wafer stack. The structure is annealed, and the top surface of the three-wafer stack is polished so that the thickness of the bound mirror wafer is about 8 microns. The surface is oxidized to have a layer of dielectric SiO2.

As shown in FIG. 7D, a set of trenches 166 for contacting the electrodes of the handle wafer is patterned and etched. The etching can be a combination of deep RIE and oxide etches.

As shown in FIG. 7E, the trenches can then be lined with tetraethylorthosilicate-derived SiO2 in a LPCVD process. The SiO2 is then etched (e.g., an oxide etch), preferably from the bottom of the trenches by a directional etching process. The trenches are then filled with in situ doped polysilicon, and the top surface of the polysilicon electrodes are polished with a conventional CMP process. The top surface of the three-wafer stack is then coated with tetraethylorthosilicate-derived SiO2. As shown in FIG. 7F, this SiO2 layer is patterned and etched to reveal the electrodes formed in the previous steps. Titanium/gold is deposited and patterned using a lift-off procedure to form electrical connections 168 and the mirror 170. FIG. 7G shows patterning of a passivating nitride layer.

FIG. 7H illustrates the start of the mirror release process. The area surrounding the mirror at the top surface is patterned and etched (using, e.g., a DRIE) to a depth of about 4 microns, as shown by the dashed line 172. Oxide 174 is deposited in a low temperature process, then patterned and etched so that it selectively covers and protects the electrodes and the area that will form the suspension springs.

As shown in FIG. 7I, a xenon difluoride etch is used to remove the silicon around and underneath the mirror surface, leaving the mirror structure suspended over the electrodes 106 by the suspension springs, which were protected by the oxide layer 174 deposited in FIG. 7H. As shown in FIG. 7J, the oxide around the electrodes is etched, exposing the electrode contacts to provide the device 100 of FIG. 2A.

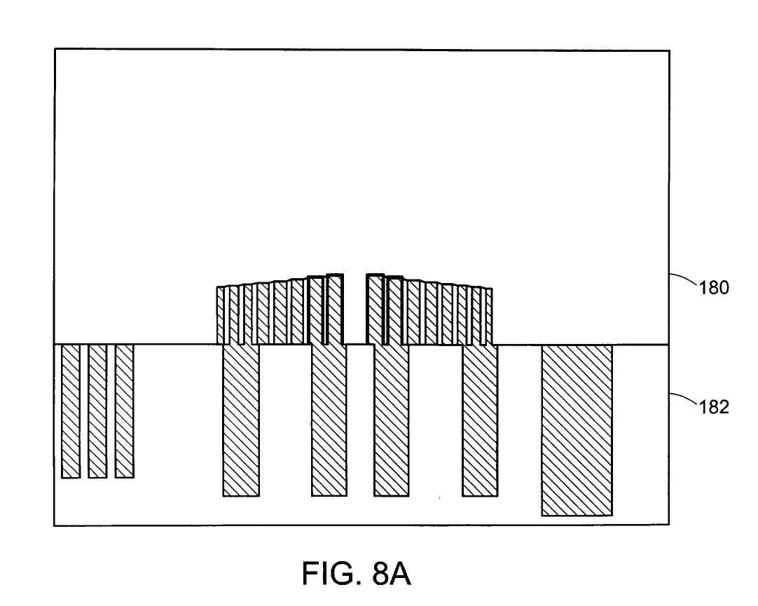

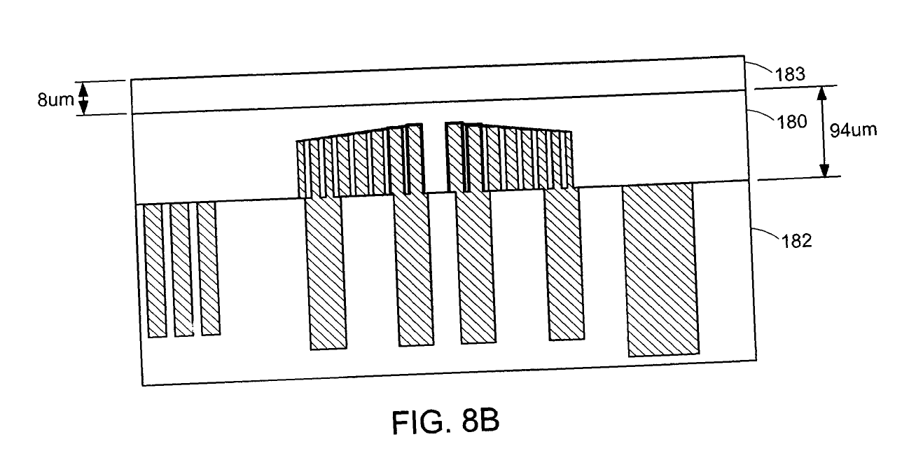

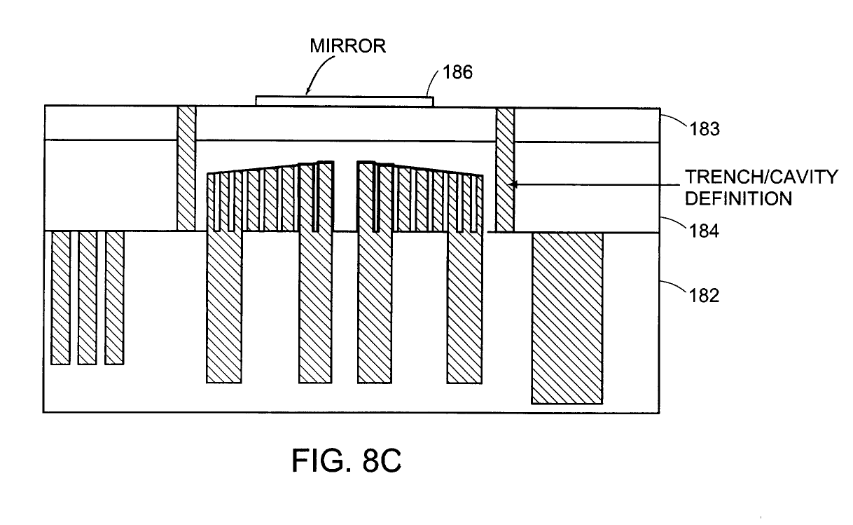

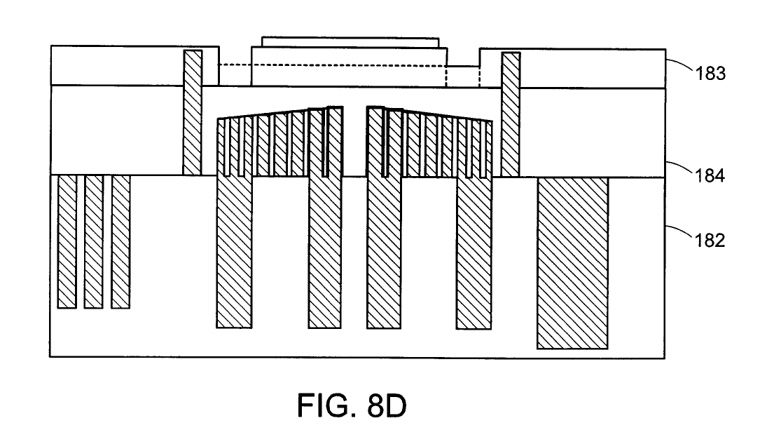

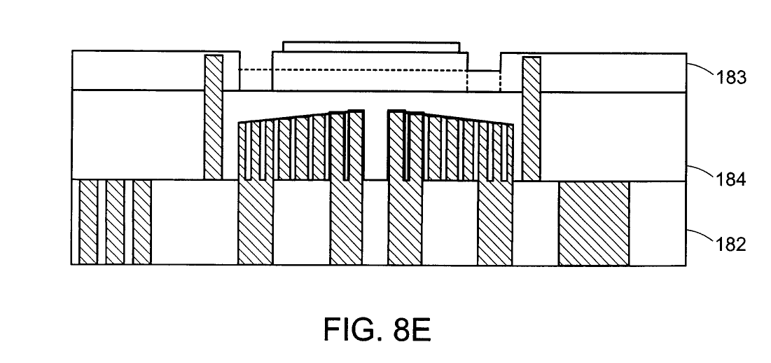

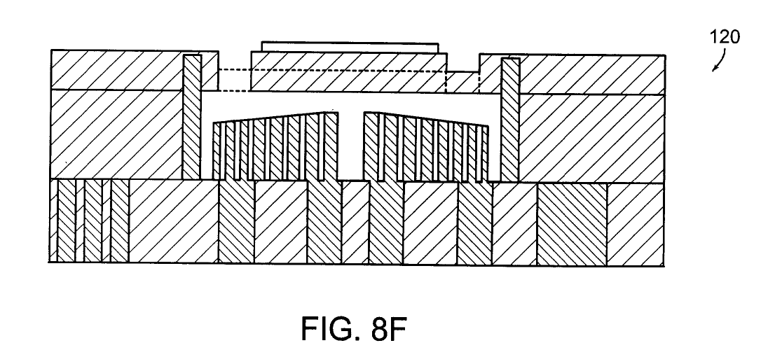

An exemplary method of making the device with backside (flipchip) contacts is illustrated in FIGS. 8A-8F. As shown in FIG. 8A, the middle wafer 180 (formed as previously described with respect to FIGS. 6A-6F) is inverted and bonded to the handle wafer 182 (formed as previously described in connection with FIGS. 4A-4D).

As shown in FIG. 8B, the top surface of the two-wafer stack (which was previously the bottom surface of the middle wafer) is ground and polished so that the thickness of the bound middle wafer is about 94 microns. The top wafer 183 from which the mirror will be formed is bonded to the top surface of the two-wafer stack, and the bond is annealed (e.g., at 1200 degrees C. for 2 hours in steam). The mirror wafer is ground and polished to a thickness of about 8 microns, and the upper surface of the mirror wafer is oxidized to yield a layer of dielectric SiO2.

As shown in FIG. 8C, trenches 184 are first patterned and etched (using, e.g., a DRIE Si etch) through the mirror wafer and the middle wafer to define the sides of the under-mirror cavity. The trenches are lined with tetraethylorthosilicate-derived SiO2, and filled with polysilicon. The top surface is polished using a conventional CMP method. A titanium/gold mirror 186 is deposited and patterned using a lift-off method.

As shown in FIG. 8D, the mirror release process is begun similar to the process described in connection with FIG. 7H above.

As shown in FIG. 8E, the bottom of the three layer stack is ground to expose the polysilicon electrodes of the handle wafer.

FIG. 8F depicts the final steps, which are analogous to those described in connection with FIGS. 7I and 7J. Xenon difluoride etching to release the mirror followed by oxide removal provides the device 120 of FIG. 2B.

The same general steps can be used to construct the exemplary device of FIG. 2C, except the third embodiment of the handle wafer, described in connection with FIGS. 5A-5C, is used. In this process, the bottom of the handle wafer need not be ground as in FIG. 8E, since the copper electrodes already extend through the wafer.

It should be understood that the methods described herein are not limited to the fabrication of steering electrodes for MEMS mirror devices. The methods described herein can be used advantageously generally in any process where it is desired to etch trenches of differing depth into a substrate. The trenches need not be disposed such that the width (and therefore the depth) decreases radially from the center; any desired trench width distribution may be envisioned and executed by use of a judiciously designed photomask. The range of possible trench depths achievable by a single masking and etching step is determined by the dependence of etch rate on trench width, and on the minimum mask line of the photolithography process. The trenches may be filled, as in the above process, in order to fabricate raised features, or may be used as trenches in the substrate.

Having described various preferred embodiments of the present invention, it should be apparent that modifications can be made without departing from the spirit and scope of the invention.

1. A method of fabricating electrodes for an electrostatically actuated MEMS device, comprising:
patterning a surface of a wafer to define a plurality of trenches to be etched, each trench having an area selected in accordance with a desired depth of said trench;
etching said surface of said wafer to form said trenches with said etch rate being varied in accordance with the trench area such that said trenches have depths determined by respective areas thereof;
depositing an electrically conductive material in said trenches to form said electrodes; and
removing portions of the wafer surrounding said electrodes.

2. The method of claim 1 wherein said surface is patterned using a photolithography mask.

3. The method of claim 1 wherein said etching comprises a highly directional etch process.

4. The method of claim 1 wherein said pattern defines a plurality of trenches that generally decrease in area in a radial direction from a generally central location in a pattern formed by said trenches.

5. The method of claim 1 wherein said wafer comprises a silicon wafer.

6. The method of claim 1 wherein said conductive material comprises polysilicon.

7. A method of fabricating an electrode structure for an electrostatically actuated MEMS mirror device, said electrode structure having a plurality of steering electrodes of various heights, comprising:
using a mask to form a pattern on a surface of a wafer, said pattern defining a plurality of trenches, each having an area selected in accordance with a desired depth of said trench;
performing directional etching on said surface of said wafer in a single etching step to form said trenches, wherein said etch rate varies in accordance with the areas of said trenches, and said trenches accordingly have depths determined by respective areas thereof;
depositing an electrically conductive material in said trenches to form said electrodes; and
removing portions of the wafer surrounding said electrodes.

8. The method of claim 7 wherein said pattern defines a plurality of trenches that generally decrease in area in a radial direction from a generally central location in said pattern.

9. The method of claim 7 wherein said wafer comprises a silicon wafer.

10. The method of claim 7 wherein said conductive material comprises polysilicon.

11. A method of fabricating a plurality of trenches of different depths in a wafer, comprising:
using a mask to form a pattern on a surface of the wafer, said pattern defining a plurality of trenches, each having an area selected in accordance with a desired depth of said trench; and
performing directional etching on said surface of said wafer in a single etching step to form said trenches with the etch rate varying in accordance with the areas of said trenches such that said trenches have depths determined by respective areas thereof.

12. The method of claim 11 wherein said pattern defines a plurality of trenches that generally decrease in area in a radial direction from a generally central location in said pattern.

13. The method of claim 11 wherein said wafer comprises a silicon wafer.

14. A method of fabricating an electrostatically actuated MEMS mirror device, comprising:
providing a structure comprising an wafer including a plurality of trenches filled with material forming electrodes, and a mirror structure supported on said wafer above said trenches, said mirror structure comprising a mirror and a suspension mechanism for supporting said mirror with respect to said wafer, said mirror structure being covered by a protective layer;
selectively etching said structure to expose said electrodes and release said mirror structure such that said mirror is suspended by said suspension mechanism above said electrodes; and
removing said protective layer from said mirror structure.

15. The method of claim 14 further comprising aligning and affixing said wafer to a handle wafer, said handle wafer providing front-side or back-side contacts for said electrodes.

16. The method of claim 15 wherein said handle wafer comprises a through-wafer interconnect device.

17. The method of claim 14 further comprising forming said mirror structure by affixing a top wafer to said wafer and etching said top wafer to define said mirror and suspension mechanism.

18. The method of claim 17 further comprising depositing a reflective surface on said top wafer.

19. The mirror of claim 18 wherein said reflective surface comprises a titanium/gold material.

20. The method of claim 17 wherein said top wafer comprises silicon.

21. The method of claim 14 wherein said wafer comprises silicon.

22. The method of claim 14 wherein said material forming said electrodes comprises polysilicon.

23. The method of claim 14 wherein said protective layer comprises an oxide layer.

24. The method of claim 14 wherein said etching is performed using xenon difluoride.

25. The method of claim 14 wherein said trenches are formed using a mask to form a pattern on a surface of the wafer, said pattern defining a plurality of trenches, each having a width selected in accordance with a desired depth of said trench; and performing directional etching on said surface of said wafer in a single etching step to form said trenches with the etch rate varying in accordance with the widths of said trenches such that said trenches have depths determined by respective widths thereof.

26. The method of claim 25 wherein said pattern defines a plurality of trenches that generally decrease in width in a radial direction from a generally central location in said pattern.

27. An electrostatically actuated MEMS mirror device formed from a double-bonded wafer stack, comprising:
a middle wafer having a plurality of raised and inclined steering electrodes;
a top wafer including a mirror structure comprising a mirror and a suspension mechanism for rotatably supporting said mirror above and with respect to said steering electrodes; and
a handle wafer positioned below said middle wafer for providing frontside or back-side contacts for said electrodes.

28. The device of claim 27 wherein said suspension mechanism comprises a gimbal mechanism.

29. The device of claim 27 wherein said electrodes comprise polysilicon.

30. The device of claim 27 wherein said mirror comprises a mirror base with a reflective surface.

31. The device of claim 27 wherein said reflective surface comprises a gold/titanium material.

32. The device of claim 27 wherein said handle wafer comprises a through-wafer interconnect device.
